(19) United States
(12) Patent Application Publication
(10) Pub. No.: US 2026/0173826 A1
(43) Pub. Date: Jun. 18, 2026

(54) ION IMPLANTATION AND VACUUM BAKE OF EXTREME ULTRAVIOLET PHOTORESIST TO IMPROVE FINE PATTERNING PERFORMANCE

(71) Applicant: Applied Materials, Inc., Santa Clara, CA (US)

(72) Inventors: John Hautala, Beverly, MA (US); Swasti Bhatia, Gloucester, MA (US); Chih-An Hsu, Milpitas, CA (US); Huixiong Dai, San Jose, CA (US)

(73) Assignee: Applied Materials, Inc., Santa Clara, CA (US)

(21) Appl. No.: 18/985,974

(22) Filed: Dec. 18, 2024

(51) Int. Cl. H01L 21/027; H01J 37/08; H01J 37/317

(52) U.S. Cl. CPC H10P 76/2049; H01J 37/08; H01J 37/3171; H10P 76/2041; H01J 2237/31703

(57) ABSTRACT

A method of processing a semiconductor layer stack including a substrate layer, a feature layer, a hardmask layer, and a photoresist layer disposed in a stacked arrangement, the photoresist layer defining an opening, the method including performing an ion implantation process on the semiconductor layer stack, wherein an ion beam formed of an ionized dopant species is directed at a top surface of the photoresist layer, and performing a baking process on the semiconductor layer stack, whereby the photoresist layer is densified and is made less susceptible to etching.

### FIELD OF THE DISCLOSURE

Embodiments of the present disclosure relate to semiconductor processing techniques, and more particularly, to methods for improving the performance of extreme ultraviolet photoresists during the manufacture of semiconductor devices.

### BACKGROUND OF THE DISCLOSURE

Photolithography is a fundamental process in semiconductor device fabrication used to pattern specific features on semiconductor workpieces. In a typical photolithography process, a thin layer of light-sensitive material, called a “photoresist,” is applied to the surface of a workpiece. The photoresist is then exposed to ultraviolet (UV) light projected through openings in a photomask, which define a desired pattern. The photomask blocks light in certain areas, allowing the light to reach only specific parts of the photoresist. After exposure, the photoresist is developed, whereby portions of the photoresist corresponding to the desired pattern are removed. The exposed parts of the underlying workpiece (unprotected by the photoresist) are then etched away using chemical or plasma etching, thus transferring the pattern from the photoresist to the material of the workpiece. Finally, the remaining photoresist material is removed, leaving behind the patterned features on the workpiece.

Extreme Ultraviolet (EUV) lithography is a cutting-edge technology used in semiconductor manufacturing to create extremely small and precise patterns on semiconductor workpieces. EUV utilizes light with a wavelength of 13.5 nanometers, which is in the extreme ultraviolet spectrum. This short wavelength allows for the creation of very small features on workpieces, essential for producing advanced microprocessors and memory devices. High Numerical Aperture Extreme Ultraviolet (High NA EUV) lithography is an advanced version of EUV lithography. “Numerical aperture” (NA) refers to a measure of the light-gathering ability of a lens system in a lithography tool. High NA EUV increases the NA, enabling even smaller and more precise patterns to be created on semiconductor workpieces. This is critical for continuing to scale down semiconductor features as it allows for higher resolution and better pattern fidelity in chip manufacturing.

Photoresists used in EUV and High NA EUV lithography processes are extremely thin, and the features defined by such photoresists are extremely small (e.g., less than 20 nanometers in various dimensions). These attributes pose new materials science and process integration challenges. For example, the stochastic effects of reduced photon counts associated with EUV and High NA EUV lithography systems can result in increased undesirable feature non-uniformity, including increased line edge roughness (LER), increased line width roughness (LWR), and decreased local critical dimension uniformity (LCDU). The small photoresist features have low thermal budgets for post-lithography processes, such as reactive ion etching. Even temperatures of 200-300 Celsius can degrade or destroy the photoresist features. Moreover, due to the thinness of photoresists used in EUV and High NA EUV lithography processes, it can be challenging to fully transfer a desired pattern to an underlying device or hard mask material layer before the photoresist features are partially or entirely etched away.

With respect to these and other considerations the present improvements may be useful.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

A method of processing a semiconductor layer stack is presented, wherein the semiconductor layer stack may include a substrate layer, a feature layer, a hardmask layer, and a photoresist layer disposed in a stacked arrangement, the photoresist layer defining an opening, wherein the method includes performing an ion implantation process on the semiconductor layer stack, wherein an ion beam formed of an ionized dopant species is directed at a top surface of the photoresist layer, and performing a baking process on the semiconductor layer stack, whereby the photoresist layer is densified and is made less susceptible to etching.

Another method of processing a semiconductor layer stack is presented, wherein the semiconductor layer stack may include a substrate layer, a feature layer, and a hardmask layer disposed in a stacked arrangement, the wherein method includes applying a photoresist layer to the hardmask layer, performing a photolithography process on the photoresist layer to form an opening therein, performing an ion implantation process on the semiconductor layer stack, wherein an ion beam formed of an ionized dopant species is directed at a top surface of the photoresist layer, and performing a baking process on the semiconductor layer stack, whereby the photoresist layer is densified and is made less susceptible to etching.

A beam-line ion implanter according to an embodiment of the present disclosure may include an ion source for generating an ion beam, an end station including a platen for supporting a semiconductor layer stack to be processed, the end station adapted to heat the semiconductor layer stack, and a main controller operatively coupled to the ion source and to the end station and adapted to control operation thereof according to software stored in a memory of the main controller, such operation including performing an ion implantation process on the semiconductor layer stack, wherein the ion beam is directed at a top surface of a photoresist layer of the semiconductor layer stack, and performing a baking process on the semiconductor layer stack, whereby the photoresist layer is densified and is made less susceptible to etching.

### BRIEF DESCRIPTION OF THE DRAWINGS

By way of example, various embodiments of the disclosed techniques will now be described with reference to the accompanying drawings, wherein:

FIGS. 1A-1I are a series of cross-sectional views illustrating an exemplary process for improving the performance of extreme ultraviolet photoresists during the manufacture of semiconductor devices;

FIG. 2 is a flow diagram summarizing the processes shown in FIGS. 1A-1I; and

FIG. 3 is a schematic view illustrating an example of a beam-line ion implanter in accordance with the present disclosure.

### DETAILED DESCRIPTION

The present embodiments will now be described more fully hereinafter with reference to the accompanying drawings, wherein some exemplary embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

The present embodiments provide novel techniques for enhancing the ability of photoresists used in EUV and High NA EUV lithography processes to withstand various post-lithography processes, including, and not limited to, heating (e.g., heated implant, etch, or deposition processes), ion etching, plasma etching, chemical etching, etc. These techniques have been developed as a result of the inventors'discovery that the stability of chemically amplified EUV and High-NA EUV photoresists can be greatly improved through a combination of ion implantation and vacuum baking.

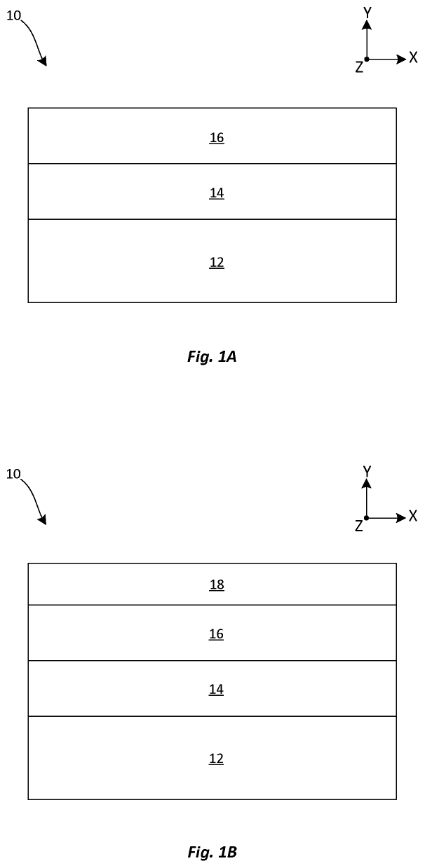

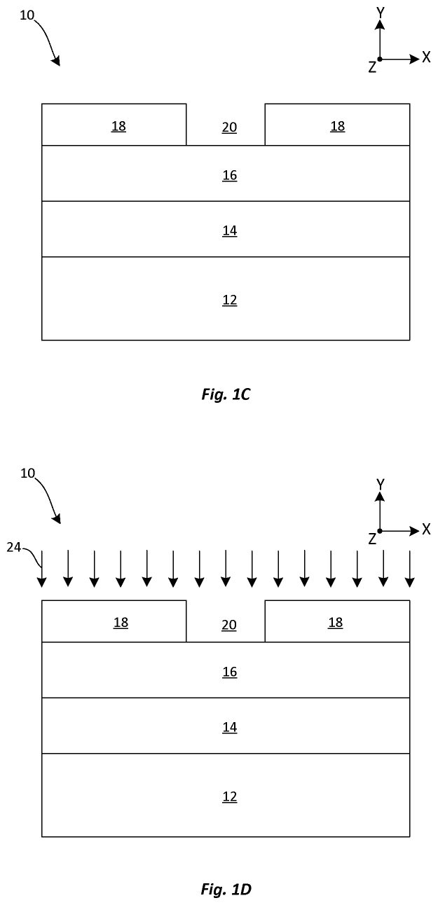

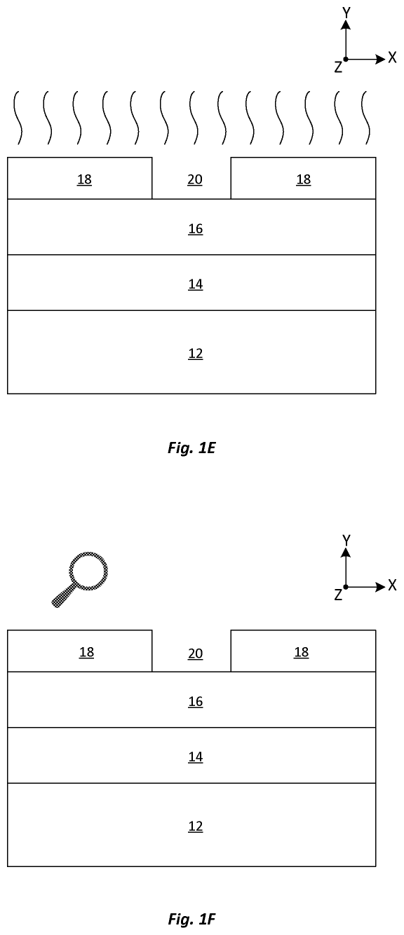

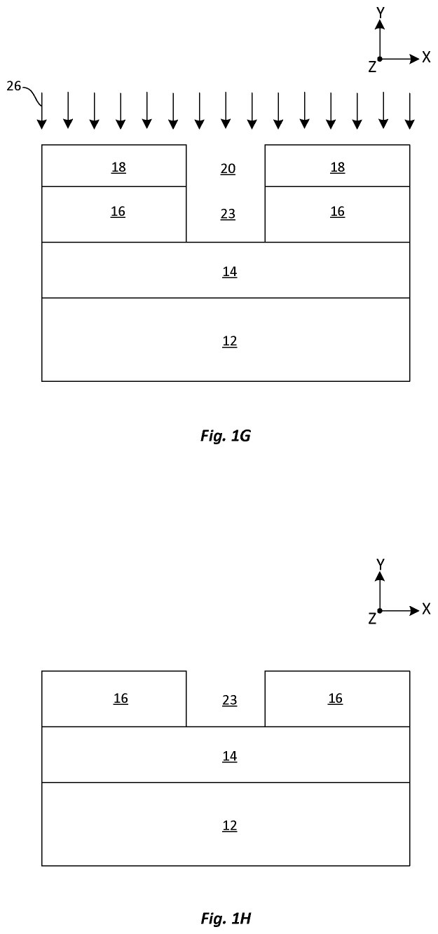

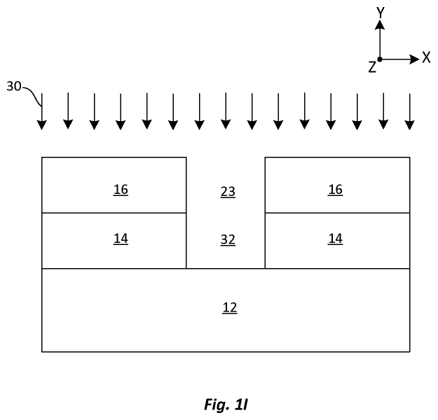

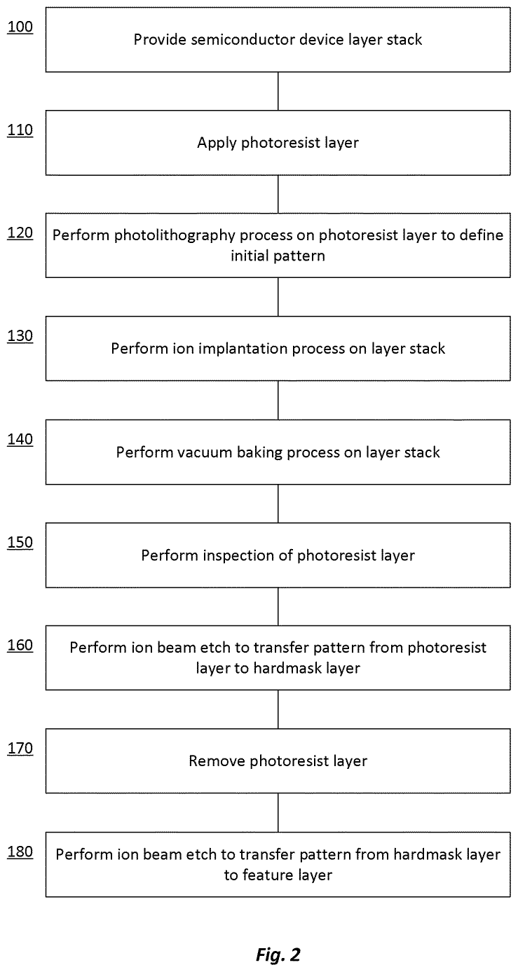

Referring to FIGS. 1A-1I, a series of cross-sectional views illustrating an exemplary process for stabilizing photoresists used in EUV and High NA EUV lithography processes are shown. Referring to FIG. 2, a flow diagram summarizing the exemplary processes illustrated in FIGS. 1A-1I is provided. For the sake of convenience and clarity, terms such as “top,” “bottom,” “upper,” “lower,” “vertical,” “horizontal,” “lateral,” and “longitudinal,” may be used herein to describe the relative position and orientation of various structures and features, all with respect to the geometry and orientation of the structures and features as they appear in the views shown in FIGS. 1A-1I. Said terminology is not intended to be limiting and includes the words specifically mentioned, derivatives thereof, and words of similar import.

Referring to FIG. 1A and block 100 in FIG. 2, a semiconductor device layer stack 10 (hereinafter “the layer stack 10”) may be provided for facilitating a semiconductor device fabrication process. The layer stack 10 may include a substrate layer 12, a feature layer 14, and a hardmask layer 16 disposed in a vertically stacked arrangement in the aforementioned order. The substrate layer 12 may be formed of a semiconductor material including, and not limited to, silicon (e.g., crystalline silicon), germanium, silicon carbide, gallium arsenide, gallium nitride, etc. The feature layer 14 may be formed of a semiconductor material that is the same as, or different from, the semiconductor material of the substrate layer 12. The hardmask layer 16 may be formed of silicon nitride, silicon carbide, silicon oxide, amorphous carbon, various metals, etc.

Referring to FIG. 1B and block 110 in FIG. 2, a chemically amplified EUV or High NA EUV photoresist layer 18 (hereinafter “the photoresist layer 18”) may be applied to a top surface of the hardmask layer 16. The photoresist layer 18 may be formed of any conventional, light-sensitive material amenable to EUV or High NA EUV photolithography processes as will be familiar to those of ordinary skill in the art, and may include a polymer matrix, a photoacid generator, various additives (sensitivity enhancers, antireflective coatings, etc.), fillers and stabilizers, crosslinkers, etc. The photoresist layer 18 may be applied to the hardmask layer 16 using any suitable process, including, and not limited to, spin coating or the like. In various embodiments, the photoresist layer may have a thickness (measured along the Y-axis of the illustrated Cartesian coordinate system) in a range of 10 nanometers to 50 nanometers. The present disclosure is not limited in this regard.

Referring to FIG. 1C and block 120 in FIG. 2, a photolithography process may be performed on the photoresist layer 18, wherein one or more portions of the photoresist layer 18 may be removed to define a desired pattern in the photoresist layer 18 for subsequent transferal to the underlying layers of the layer stack 10 as further described below. As will be familiar to those of skill in the art, the photolithography process may include ultraviolet light exposure, developing, post exposure baking, inspection, etc. The present disclosure is not limited in this regard. The photolithography process may result in the formation of one or more openings 20 in the photoresist layer 18. Only one opening 20 is shown in figures of the present disclosure, though it will be understood that additional openings may be similarly and simultaneously formed in the photoresist layer 18 via the photolithography process. The opening 20 may correspond to a trench, via, contact window, or other semiconductor device feature intended to ultimately be formed in the feature layer 14 of the layer stack 10 as further described below. The opening 20 may have a width (measured along the X-axis of the illustrated Cartesian coordinate system) in a range of 10 nanometers to 100 nanometers.

Referring to FIG. 1D and block 130 in FIG. 2, the layer stack 10 may be subjected to an ion implantation process, wherein an ion beam 24 formed of an ionized dopant species is extracted from an adjacent ion beam source (not shown) and is directed at a top surface of the photoresist layer 18. The ion beam may interact with the photoresist layer 18 as well as the exposed portion of the hardmask layer 16 below the opening. In various embodiments, the dopant species used for the ion implantation process may be a noble gas such as Argon, Neon, Krypton, or Xenon. The present disclosure is not limited in this regard. In various embodiments, the ion beam 24 may be directed at the top surface of the photoresist layer 18 at an angle in a range of 0 to 60 degrees from normal relative thereto, at an energy in a range of 0.7 to 10 keV, and provides an implantation dose in a range of 1e14 to 1e16 ions/cm². The present disclosure is not limited in this regard.

Referring to FIG. 1E and block 140 in FIG. 2, the layer stack 10 may be subjected to a vacuum baking or annealing process (hereinafter “the vacuum baking process” or “the baking process”) wherein the layer stack is heated in a vacuum (or low pressure, near vacuum) environment. The vacuum baking process may be performed at a temperature in a range of 250-400 degrees Celsius, at a pressure in a range of 1e−7 to 1e−4 Torr, and for a time in a range of 0.5 to 10 minutes. The present disclosure is not limited in this regard. As briefly discussed above, the inventors of the present disclosure have found through experimentation that by subjecting the layer stack 10 to this vacuum baking process after performing the above-described ion implantation process, the photoresist layer 18 may be densified or stabilized such that the small features defined by the photoresist layer 18 (e.g., edges of the photoresist layer 18 defining the opening 20) are made more robust to prevent them from being distorted or erased during post-lithographic processing (e.g., reactive ion etching, chemical etching, chemical vapor deposition, atomic layer deposition, soft and hard bakes, follow-up resist coating and baking, plasma processing, subsequent ion implantation, etc.), especially during processes that are performed at elevated temperatures.

Additionally, the above-described ion implantation process and vacuum baking process (hereinafter collectively referred to as “the photoresist stabilization treatment”) may serve to enhance etch selectivity in the layer stack 10, whereby the susceptibility of the of the photoresist layer 18 to a subsequent etching process is decreased relative to the hardmask layer 16 (due to the densification of the photoresist layer 18) and/or the susceptibility of the of the hardmask layer 16 to a subsequent etching process is increased relative to the photoresist layer 18 (due to implantation-based damage in the hardmask layer 16). Thus, when the layer stack 10 is subjected to an etching process (as further described below), the exposed portion of the hardmask layer 16 (i.e., the portion of the hardmask layer 16 below the opening 20 in the photoresist layer 18) may be preferentially removed relative to the photoresist layer 18. The photoresist layer 18 and the features defined thereby may therefore remain intact until the etching process is complete and the features of the photoresist layer 18 are completely transferred to the hardmask layer 16.

Furthermore, the photoresist stabilization treatment may decrease the line edge roughness (LER) of patterned line/space (L/S) features in the photoresist layer 18 by over 10% (15% demonstrated in experiments), decrease the line width roughness (LWR) of patterned L/S features in the photoresist layer 18 by over 15% (22% demonstrated in experiments), and increase the local critical dimension uniformity (LCDU) of all patterned features by similar amounts without changing the critical dimensions (CDs) of the features.

Referring to FIG. 1F and block 150 in FIG. 2, a critical dimension scanning electron microscope (CD-SEM) and/or other metrology or inspection equipment may be employed to measure the LER, LWR, LCDU, and CDs of the opening 20 to verify that such parameters are equal to desired/expected values or fall within desired/expected ranges.

Referring to FIG. 1G and block 160 in FIG. 2, the layer stack 10 may be subjected to an etching process (e.g., reactive ion etching, chemical etching, etc.), wherein the pattern defined by the photoresist layer 18 may be transferred to the hardmask layer 16. For example, in the case of reactive ion etching (RIE), chemically reactive ions 26 may be generated by an adjacent ion source (not shown) and may be directed at a top surface of the layer stack 10 at a perpendicular angle thereto. The ions 22 may pass through the opening 20 in the photoresist layer 18 and may preferentially remove (i.e., etch) the exposed material of the hardmask layer 16, thus forming a corresponding opening 23 in the hardmask layer 16 and exposing the underlying feature layer 14. As discussed above, the photoresist stabilization treatment performed on the layer stack 10 may make the photoresist layer 18 less susceptible to the etching process such that features defined thereby (e.g., edges of the photoresist layer 18 defining the opening 20) may remain intact until the etching process is complete and such features, including the critical dimensions of such features, are completely and faithfully transferred to the hardmask layer 16. For example, attributes such as the LER, LWR, and LCDU of the opening 20 are substantially duplicated in the opening 23 formed in the hardmask layer 16.

Referring to FIG. 1H, and block 170 in FIG. 2, the photoresist layer 18 may be removed from layer stack 10 to expose the top surface of the hardmask layer 16. In various embodiments, the photoresist layer 18 may be removed using various solvents, plasma ashing, wet chemicals, or other techniques familiar to those of ordinary skill in the art. The present disclosure is not limited in this regard.

Referring to FIG. 1I, and block 180 in FIG. 2, the layer stack 10 may be subjected to another etching process, wherein the pattern defined by the hardmask layer 16 (e.g., the opening 23), may be transferred to the feature layer 14. For example, in the case of reactive ion etching (RIE), a beam 30 formed of chemically reactive ions may be generated by an adjacent ion beam source (not shown) and may be directed at a top surface of the layer stack 10 at a perpendicular angle thereto. The beam 30 may pass through the opening 23 formed in the hardmask layer 16 and may preferentially remove (i.e., etch) the exposed material of the feature layer 14, thus forming a corresponding opening 32 in the feature layer 14 and exposing the substrate layer 12. Particularly, the opening 32 may have the same (or nearly the same), precisely defined dimensions and attributes of the opening 23 in the hardmask layer 16 achieved using the photoresist stabilization treatment described above. Thus, the critical dimensions, LER, LWR, and LCDU of the opening 20 originally formed and defined in the photoresist layer 18 may be faithfully reproduced in the feature layer 14.

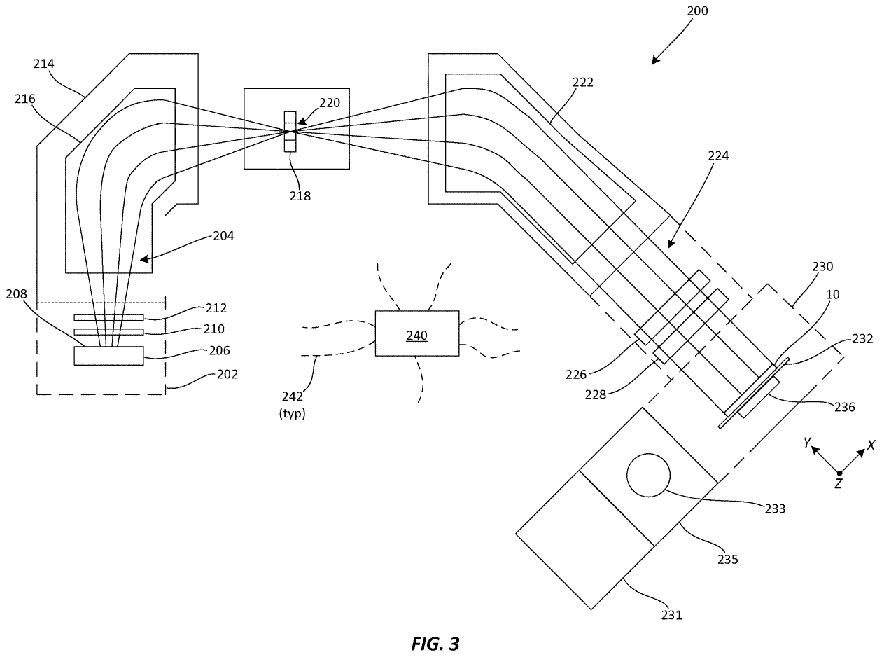

Referring to FIG. 3, a schematic diagram illustrating an example of a beam-line ion implanter 200 capable of performing the photoresist stabilization treatment described above is shown. The beam-line ion implanter 200 is one of many examples of beam-line ion implanters capable of performing the photoresist stabilization. Thus, the systems and methods disclosed herein are not limited to implementation with the beam-line ion implanter 200 of FIG. 3. Various types of ion implanters can be substituted for the beam-line ion implanter 200 as may be suitable for a particular application.

In general, the beam-line ion implanter 200 (hereinafter “the implanter 200”) may include an ion source 202 adapted to generate ions for forming an ion beam 204. The ion source 202 may include an ion chamber 206 where the ions are produced. The generated ions may be extracted from the ion chamber 206 by a series of extraction electrodes to form the ion beam 204. In particular, the ions may be extracted from chamber 206 by an extraction electrode 208 (e.g., integral with an exit aperture of the ion chamber 206), a suppression electrode 210, and a ground electrode 212.

The ion beam 204 may be mass analyzed by mass analyzer 214 having a resolving magnet 216 and a masking electrode 218 having a resolving aperture 220. The resolving magnet 216 deflects ions in the ion beam 204 to isolate ions having a desired mass-to-charge ratio associated with a particular dopant ion species subsequently allowed to pass through the resolving aperture 220. Undesired ion species are deflected into, and blocked, by the masking electrode 218 and thus do not pass through the resolving aperture 220.

Ions of the desired ion species pass through resolving aperture 220 to an angle corrector magnet 222. The angle corrector magnet 222 deflects ions of the desired ion species and converts the ion beam from a diverging ion beam to a focused ion beam 224 (e.g., a ribbon beam or a spot beam) having generally parallel ion trajectories. The implanter 200 may further include acceleration unit 226 and/or a deceleration unit 228. The acceleration and deceleration units 226, 228 may be used to speed up or slow down the focused ion beam 224. Speed adjustment is accomplished by applying specific combinations of voltage potentials to sets of electrodes disposed on opposite sides of the focused ion beam 224. As the focused ion beam 224 passes between the electrodes, ion energies are increased or decreased depending on the applied voltage potentials. Since the depth of an ion implant is proportional to the energy of the impinging ion beam, beam acceleration may be desirable when performing deep ion implants. Conversely, where shallow ion implants are desired, beam deceleration is performed to ensure the impinging ions travel only a short distance into the workpiece.

An end station 230 of the implanter 200 may define a chamber that houses a platen 232 configured to support a workpiece, such as the layer stack 10 described above. An interior of the end station 230 may be held at vacuum (or low pressure, near vacuum). The layer stack 10 may be disposed in the path of the focused ion beam 224, and ions of a desired ion species may be implanted into the layer stack 10. The end station 230 may include a scanner 236 adapted to move the platen 232 and the layer stack 10 perpendicular to the long dimension of the focused ion beam 224 (i.e., along the X-axis of the illustrated Cartesian coordinate system) for distributing ions over the entire surface of the layer stack 10. The scanner 236 may further be adapted to move the platen 232 and the layer stack 10 parallel to the long dimension of the focused ion beam 224 (i.e., along the Y-axis of the illustrated Cartesian coordinate system). The scanner 236 may further be adapted to tilt or rotate the platen 232 and the layer stack 10 relative to the focused ion beam 224 (e.g., rotate the platen 232 and the layer stack 10 about the Y-axis of the illustrated Cartesian coordinate system). The present disclosure is not limited in this regard.

The implanter 200 may further include a heating chamber 231, separate from the end station 230, within which the layer stack 10 may be heated before or after being processed (e.g., implanted or etched) in the end station 230, such as for performing the above-described vacuum baking process. The heating chamber 231 may be thermally insulated/isolated from the end station 230, and heating of the layer stack 10 within the heating chamber 231 may be achieved using any known technique, including, and not limited to, backside heating, ambient heating, etc. The present disclosure is not limited in this regard. In various embodiments, the layer stack 10 may be transferred between the end station 230 and the heating chamber 231 by a transfer robot 233 located in a transfer chamber 235 intermediate the end station 230 and the heating chamber 231. Thus, in various embodiments of the present disclosure, the entire photoresist stabilization treatment described above, including the ion implantation process and the vacuum baking process, may be performed within the implanter 200. Alternatively, the ion implantation process(es) described above may be performed within the implanter 200, and the vacuum baking process may be performed by a separate system or apparatus external to the implanter 200. The present disclosure is not limited in this regard.

The implanter 200 may further include a main controller 240 operatively coupled to one or more of the ion source 202, the mass analyzer 214, the angle corrector magnet 222, the acceleration unit 226, the deceleration unit 228, the scanner 236, the end station 230, the heating chamber 231, etc., by various data lines (as indicated by the dashed lines 242) for controlling and coordinating the operation of the aforementioned components. The main controller 240 may include a processor, such as a known type of microprocessor, dedicated semiconductor processor chip, general purpose semiconductor processor chip, or similar device. The main controller 240 may further include a memory or memory unit coupled to the processor, where the memory unit may contain software for executing various processes described above (e.g., the photoresist stabilization treatment).

The memory unit of the main controller 240 may comprise an article of manufacture. In one embodiment, the memory unit may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

Those of skill in the art will recognize the numerous advantages provided by the processes disclosed herein. For example, the above-described photoresist stabilization treatment may be densify or stabilize a photoresist layer such that small features defined by the photoresist layer 18 are made more robust to prevent them from being distorted or erased during post-lithographic processing (e.g., reactive ion etching, chemical etching, chemical vapor deposition, atomic layer deposition, soft and hard bakes, follow-up resist coating and baking, plasma processing, subsequent ion implantation, etc.), especially during processes that are performed at elevated temperatures. Thus, the CD, LER, LWR, and LCDU of the features originally formed and defined in the photoresist layer may be faithfully reproduced in underlying layers of a workpiece. Additionally, the photoresist stabilization treatment may enhance the etch selectivity of a photoresist layer relative to an underlying hardmask layer.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A method of processing a semiconductor layer stack including a substrate layer, a feature layer, a hardmask layer, and a photoresist layer disposed in a stacked arrangement, the photoresist layer defining an opening, the method comprising:
performing an ion implantation process on the semiconductor layer stack, wherein an ion beam formed of an ionized dopant species is directed at a top surface of the photoresist layer; and
performing a baking process on the semiconductor layer stack, whereby the photoresist layer is densified and is made less susceptible to etching.

2. The method of claim 1, further comprising performing an etching process on the layer stack, wherein a pattern defined by the opening in the photoresist layer is transferred to the hardmask layer.

3. The method of claim 1, wherein the ion implantation process is performed in an end station of an ion implanter, and wherein the baking process is performed in a heating chamber of the ion implanter.

4. The method of claim 1, wherein the photoresist layer is a chemically amplified extreme ultraviolet photoresist layer.

5. The method of claim 1, wherein the dopant species is one of Argon, Neon, Krypton, and Xenon.

6. The method of claim 1, wherein the ion beam is directed at the top surface of the photoresist layer at an angle in a range of 0 to 60 degrees from normal relative thereto.

7. The method of claim 1, wherein the ion beam has an energy in a range of 0.7 to 10 keV.

8. The method of claim 1, wherein the ion beam provides an implantation dose in a range of 1e14 to 1e16 ions/cm2.

9. The method of claim 1, wherein the baking process is performed at a temperature in a range of 250-400 degrees Celsius.

10. The method of claim 1, wherein the baking process is performed at a pressure in a range of 1e−7 to 1e−4 Torr.

11. The method of claim 1, wherein the baking process is performed for a time in a range of 0.05 to 10 minutes.

12. A method of processing a semiconductor layer stack including a substrate layer, a feature layer, and a hardmask layer disposed in a stacked arrangement, the method comprising:
applying a photoresist layer to the hardmask layer;
performing a photolithography process on the photoresist layer to form an opening therein;
performing an ion implantation process on the semiconductor layer stack, wherein an ion beam formed of an ionized dopant species is directed at a top surface of the photoresist layer; and
performing a baking process on the semiconductor layer stack, whereby the photoresist layer is densified and is made less susceptible to etching.

13. A beam-line ion implanter comprising:
an ion source for generating an ion beam;
an end station including a platen for supporting a semiconductor layer stack to be processed;
a heating chamber adapted to heat the semiconductor layer stack; and
a main controller operatively coupled to the ion source, the end station, and the heating chamber and adapted to control operation thereof according to software stored in a memory of the main controller, such operation including:
performing an ion implantation process on the semiconductor layer stack, wherein the ion beam is directed at a top surface of a photoresist layer of the semiconductor layer stack; and
performing a baking process on the semiconductor layer stack, whereby the photoresist layer is densified and is made less susceptible to etching.

14. The beam-line ion implanter of claim 13, wherein a dopant species used for the ion implantation process is one of Argon, Neon, Krypton, and Xenon.

15. The beam-line ion implanter of claim 13, wherein the ion beam is directed at the top surface of the photoresist layer at an angle in a range of 0 to 60 degrees from normal relative thereto.

16. The beam-line ion implanter of claim 13, wherein the ion beam has an energy in a range of 0.7 to 10 keV.

17. The beam-line ion implanter of claim 13, wherein the ion beam provides an implantation dose in a range of 1e14 to 1e16 ions/cm2.

18. The beam-line ion implanter of claim 13, wherein the baking process is performed at a temperature in a range of 250-400 degrees Celsius.

19. The beam-line ion implanter of claim 13, wherein the baking process is performed at a pressure in a range of 1e−7 to 1e−4 Torr.

20. The beam-line ion implanter of claim 13, wherein the baking process is performed for a time in a range of 0.5 to 10 minutes.
